(19) United States
(12) Patent Application Publication
(10) Pub. No.: US 2025/0286008 A1
(43) Pub. Date: Sep. 11, 2025

(54) SEMICONDUCTOR DEVICE AND SEMICONDUCTOR MODULE

(71) Applicant: KABUSHIKI KAISHA TOSHIBA, Tokyo (JP)

(72) Inventor: Tatsunori SAKANO, Tokyo (JP)

(73) Assignee: KABUSHIKI KAISHA TOSHIBA, Tokyo (JP)

(21) Appl. No.: 19/062,317

(22) Filed: Feb. 25, 2025

(30) Foreign Application Priority Data
Mar. 8, 2024 (JP) 2024-036087

(51) Int. Cl. H01L 23/00; H01L 25/16; H10D 8/00; H10D 12/00; H10D 62/832

(52) U.S. Cl. CPC H01L 24/32; H01L 25/162; H10D 12/415; H10D 62/8325; H01L 2224/26145; H01L 2224/32058; H01L 2224/32059; H01L 2224/32112; H01L 2224/32148; H01L 2924/12036; H01L 2924/13055; H10D 8/411

(57) ABSTRACT

A first bonding member is located between a first electrode of a second chip and a second electrode of a first chip in a first direction and between a first electrode of the second chip and a protective film of the first chip in the first direction. The first bonding member electrically connects the second electrode of the first chip and the first electrode of the second chip in an opening of the protective film of the first chip. The protective film of the first chip includes a first recess in a surface of the protective film of the first chip facing the first electrode of the second chip. A portion of the first bonding member is located in the first recess.

### CROSS-REFERENCE TO RELATED APPLICATION

This application is based upon and claims the benefit of priority from Japanese Patent Application No. 2024-036087, filed on Mar. 8, 2024; the entire contents of which are incorporated herein by reference.

### FIELD

Embodiments described herein relate generally to a semiconductor device and a semiconductor module.

### BACKGROUND

IGBTs (Insulated Gate Bipolar Transistors) are widely used as power semiconductor devices that control high breakdown voltages and large currents.

### BRIEF DESCRIPTION OF THE DRAWINGS

FIG. 1 is a schematic cross-sectional view of a first chip and a second chip of a semiconductor device of an embodiment;

FIG. 2 is a schematic plan view of the first chip and the second chip of the embodiment;

FIG. 3 is an equivalent circuit diagram of the semiconductor device of the embodiment;

FIG. 4 is a schematic plan view of a semiconductor module of an embodiment;

FIG. 5 is a schematic cross-sectional view of the semiconductor module of the embodiment; and

FIG. 6 is a schematic cross-sectional view of a first chip and a second chip according to a modified example of the embodiment.

### DETAILED DESCRIPTION

According to one embodiment, a semiconductor device includes a first chip and a second chip stacked in a first direction; and a first bonding member located between the first chip and the second chip in the first direction, the first chip and the second chip each including a semiconductor part including a first surface, and a second surface positioned at a side opposite to the first surface in the first direction, a first electrode located at the first surface, a second electrode located at a portion of the second surface, and a protective film partially covering the second surface, the protective film including an opening that exposes the second electrode, the first bonding member being located between the first electrode of the second chip and the second electrode of the first chip in the first direction and between the first electrode of the second chip and the protective film of the first chip in the first direction, the first bonding member electrically connecting the second electrode of the first chip and the first electrode of the second chip in the opening of the protective film of the first chip, the protective film of the first chip including a first recess in a surface of the protective film of the first chip facing the first electrode of the second chip, a portion of the first bonding member being located in the first recess.

Exemplary embodiments will now be described with reference to the drawings.

The drawings are schematic or conceptual; and the relationships between the thickness and width of portions, the proportional coefficients of sizes among portions, etc., are not necessarily the same as the actual values thereof. Furthermore, the dimensions and proportional coefficients may be illustrated differently among drawings, even for identical portions.

In the specification of the application and the drawings, components similar to those described in regard to a drawing thereinabove are marked with like reference numerals, and a detailed description is omitted as appropriate.

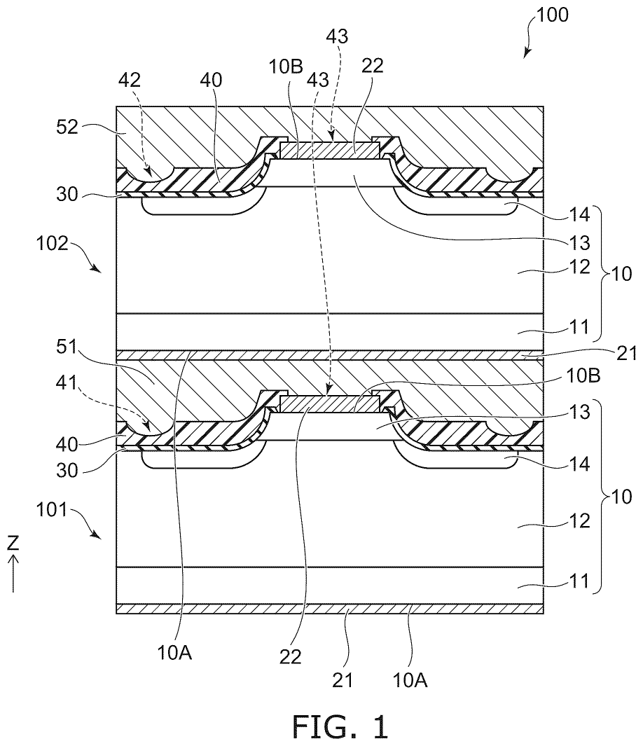

A semiconductor device 100 of an embodiment will now be described with reference to FIGS. 1 to 3.

The semiconductor device 100 includes a first chip 101, a second chip 102, and a first bonding member 51. As shown in FIG. 1, the first chip 101 and the second chip 102 are stacked in a first direction Z. A second electrode 22 of the first chip 101 and the second electrode 22 of the second chip 102 are positioned to overlap each other in the first direction Z. The first bonding member 51 is located between the first chip 101 and the second chip 102 in the first direction Z.

The first chip 101 and the second chip 102 are similarly configured. The first chip 101 and the second chip 102 each include a semiconductor part 10, a first electrode 21, the second electrode 22, and a protective film 40.

The semiconductor part 10 includes a first surface 10A, and a second surface 10B positioned at the side opposite to the first surface 10A in the first direction Z. The first electrode 21 is located at the first surface 10A. The second electrode 22 is located at a portion of the second surface 10B.

For example, the semiconductor part 10 is made of silicon carbide (SiC). In the description of the specification, a first conductivity type is taken to be an n-type; and a second conductivity type is taken to be a p-type. Or, the first conductivity type may be the p-type; and the second conductivity type may be the n-type.

The semiconductor part 10 includes an n-type first semiconductor layer 11 located on the first electrode 21, an n-type second semiconductor layer 12 located on the first semiconductor layer 11, and a p-type third semiconductor layer 13 located on the second semiconductor layer 12. The n-type impurity concentration of the second semiconductor layer 12 is less than the n-type impurity concentration of the first semiconductor layer 11. Conversely speaking, the n-type impurity concentration of the first semiconductor layer 11 is greater than the n-type impurity concentration of the second semiconductor layer 12. The thickness in the first direction Z of the second semiconductor layer 12 is greater than the thickness in the first direction Z of the first semiconductor layer 11. The first semiconductor layer 11 is electrically connected with the first electrode 21. The second electrode 22 is located on the third semiconductor layer 13; and the third semiconductor layer 13 is electrically connected with the second electrode 22.

For example, the first chip 101 and the second chip 102 each are diode chips. The first electrode 21 functions as a cathode electrode; and the second electrode 22 functions as an anode electrode. A current flows in the first direction Z between the second electrode 22 and the first electrode 21 in each of the first and second chips 101 and 102.

The protective film 40 partially covers the second surface 10B of the semiconductor part 10. The protective film 40 includes an opening 43 that exposes the second electrode 22. The protective film 40 is an insulating film, and is, for example, a resin film. The protective film 40 includes, for example, mainly polyimide.

The first bonding member 51 is conductive. The first bonding member 51 is located between the first electrode 21 of the second chip 102 and the second electrode 22 of the first chip 101 in the first direction Z and between the first electrode 21 of the second chip 102 and the protective film 40 of the first chip 101 in the first direction Z. The first bonding member 51 electrically connects the second electrode 22 of the first chip 101 and the first electrode 21 of the second chip 102 in the opening 43 of the protective film 40 of the first chip 101. The first chip 101 and the second chip 102 are connected in series via the first bonding member 51. For example, solder, silver, etc., can be used as the material of the first bonding member 51.

The protective film 40 of the first chip 101 includes a first recess 41 in the surface of the protective film 40 of the first chip 101 facing the first electrode 21 of the second chip 102. A portion of the first bonding member 51 is located in the first recess 41. By including the first recess 41, the volume of the first bonding member 51 that can be held between the first chip 101 and the second chip 102 stacked in the first direction Z is increased, and the first bonding member 51 does not easily flow out onto the side surface of the first chip 101 and the side surface of the second chip 102. As a result, unintended short-circuit defects can be suppressed, and a semiconductor device with high reliability can be provided.

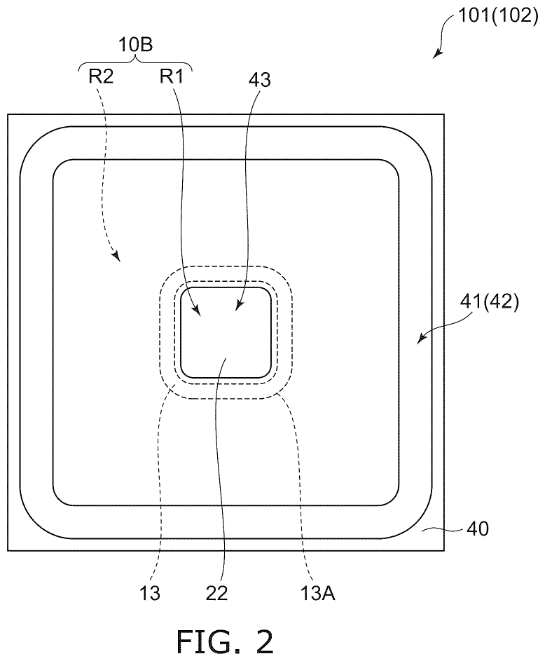

As shown in FIG. 2, it is favorable for the first recess 41 to be a trench continuously surrounding the second electrode 22 when the second surface 10B is viewed in plan. As a result, the first bonding member 51 does not easily flow out onto the side surface of the first chip 101 and the side surface of the second chip 102 in all directions around the second electrode 22. The protective film 40 of the first chip 101 contacts the first bonding member 51 in at least a portion of the region inward of the first recess 41. The protective film 40 of the first chip 101 may contact the first bonding member 51 in the region outward of the first recess 41.

As shown in FIG. 2, the second surface 10B of the semiconductor part 10 can include an element region R1 in which the p-type third semiconductor layer 13 is positioned, and a termination region R2 positioned outward of the element region R1. The termination region R2 continuously surrounds the element region R1. In FIG. 2, an outer edge 13A of the third semiconductor layer 13 can be the boundary between the element region R1 and the termination region R2.

In the termination region R2 as shown in FIG. 1, a p-type fourth semiconductor layer 14 that has a lower p-type impurity concentration than the third semiconductor layer 13 is positioned on the second semiconductor layer 12. The fourth semiconductor layer 14 continuously surrounds the third semiconductor layer 13 when viewed in plan. The portion of the fourth semiconductor layer 14 at the inner perimeter side contacts the portion of the third semiconductor layer 13 at the outer perimeter side. The p-n junction between the third semiconductor layer 13 and the second semiconductor layer 12 is positioned inward of the inner edge of the fourth semiconductor layer 14. The potential of the second electrode 22 is applied to the fourth semiconductor layer 14 via the third semiconductor layer 13. Due to the fourth semiconductor layer 14 that has a lower p-type impurity concentration than the third semiconductor layer 13, the depletion layer can easily extend into the termination region R2; and the breakdown voltages of the first and second chips 101 and 102 can be increased.

The depth of the first recess 41 is less than the thickness of the protective film 40 on the termination region R2, and so reliability degradation due to a partial thickness reduction of the protective film 40 on the termination region R2 can be suppressed. The depth and the thickness are lengths in the first direction Z. The first recess 41 has a depth of not less than 100 nm and not more than 20,000 nm and a width of not less than 100 nm.

As shown in FIG. 1, the first chip 101 and the second chip 102 each may further include an insulating film 30 located between the protective film 40 and the second surface 10B of the semiconductor part 10. The insulating film 30 is, for example, an inorganic film. The insulating film 30 is, for example, a silicon oxide film. The film thickness of the protective film 40 is, for example, several tens of times to several hundreds of times the film thickness of the insulating film 30.

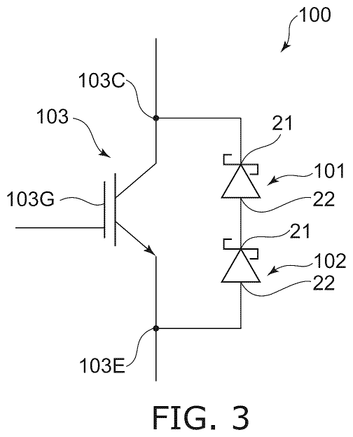

As shown in FIG. 3, the semiconductor device 100 of the embodiment can further include a third chip 103 that is connected in parallel to the first and second chips 101 and 102.

The third chip 103 is a transistor chip that includes a third electrode 103C electrically connected with the first electrode 21 of the first chip 101, and a fourth electrode 103E electrically connected with the second electrode 22 of the second chip 102. The third chip 103 is, for example, an IGBT (Insulated Gate Bipolar Transistor) chip. In the IGBT chip, the third electrode 103C is the collector electrode; and the fourth electrode 103E is the emitter electrode. The third chip 103 further includes a gate electrode 103G. The third chip 103 is, for example, an IGBT chip of a silicon material.

For example, the first chip 101 and the second chip 102 function as freewheeling diodes that carry a reverse current generated when the third chip 103 (the IGBT chip) switches in applications such as inverters, motor driving, etc. The breakdown voltage of the third chip 103 (the IGBT chip) is, for example, 4.5 kV. In the freewheeling diode of the embodiment, for example, a freewheeling diode that has a breakdown voltage of 4.5 kV is realized by using a configuration in which the first chip 101 (or the second chip 102) that has a breakdown voltage of 1.2 kV and the second chip 102 (or the first chip 101) that has a breakdown voltage of 3.3 kV are connected in series. As a result, the cost can be less than when one diode chip having a breakdown voltage of 4.5 kV is used, and the reliability can be increased.

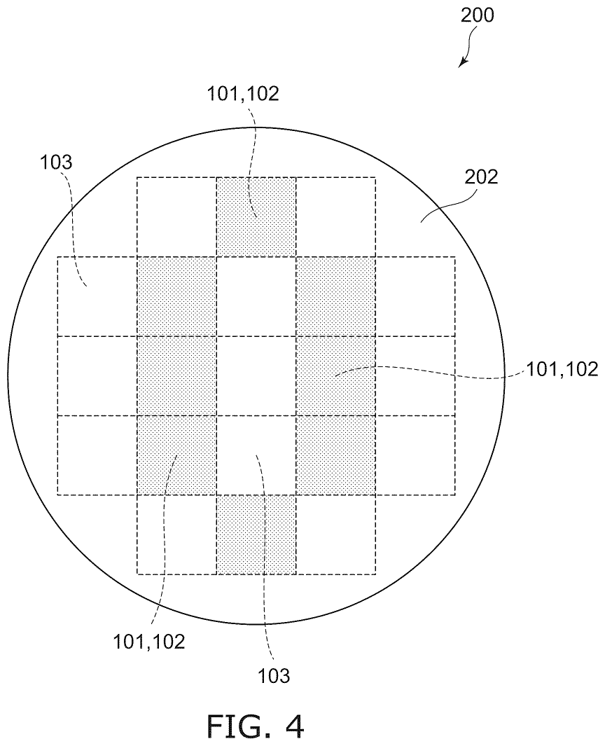

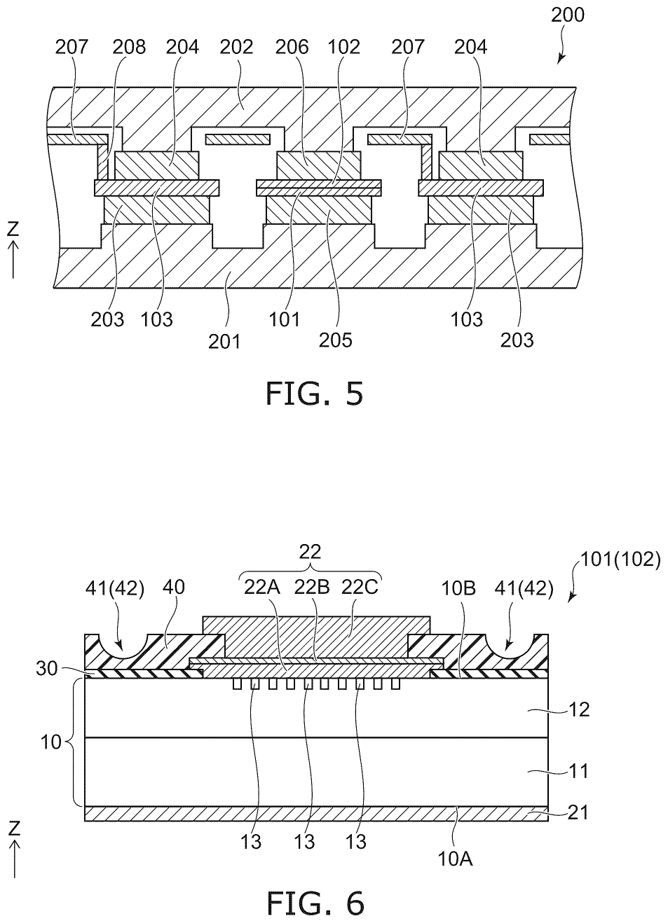

A semiconductor module 200 of an embodiment will now be described with reference to FIGS. 4 and 5.

As shown in FIG. 5, the semiconductor module 200 includes a first conductive member 201, a second conductive member 202, and a plurality of the aforementioned semiconductor devices 100 located between the first conductive member 201 and the second conductive member 202 in the first direction Z. The multiple semiconductor devices 100 each include the first to third chips 101 to 103. In other words, the semiconductor module 200 includes the multiple first chips 101, the multiple second chips 102, and the multiple third chips 103. The multiple first chips 101 and the multiple third chips 103 each are separated in a plane crossing the first direction Z. As described above, the first chip 101 and the second chip 102 are stacked with the first bonding member 51 interposed, and are connected in series. In FIG. 4, the first chip 101 and the second chip 102 that are stacked are illustrated by cross hatching.

The first electrode 21 (the cathode electrode) of the first chip 101 and the third electrode 103C (the collector electrode) of the third chip 103 are electrically connected with the first conductive member 201. A first metal plate 205 is located between the first chip 101 and the first conductive member 201; and the first conductive member 201 and the first electrode 21 of the first chip 101 are electrically connected via the first metal plate 205. A third metal plate 203 is located between the third chip 103 and the first conductive member 201; and the first conductive member 201 and the third electrode 103C of the third chip 103 are electrically connected via the third metal plate 203.

The second electrode 22 (the anode electrode) of the second chip 102 and the fourth electrode 103E (the emitter electrode) of the third chip 103 are electrically connected with the second conductive member 202. A second metal plate 206 is located between the second chip 102 and the second conductive member 202; and the second conductive member 202 and the second electrode 22 of the second chip 102 are electrically connected via the second metal plate 206. A fourth metal plate 204 is located between the third chip 103 and the second conductive member 202; and the second conductive member 202 and the fourth electrode 103E of the third chip 103 are electrically connected via the fourth metal plate 204.

For example, copper can be used as the materials of the first and second conductive members 201 and 202. The first conductive member 201 and the second conductive member 202 extend along a plane crossing the first direction Z. The first conductive member 201 and the second conductive member 202 include multiple protrusions extending along the first direction Z. The multiple protrusions contact the first metal plate 205, the second metal plate 206, the third metal plate 203, and the fourth metal plate 204. For example, molybdenum can be used as the materials of the first metal plate 205, the second metal plate 206, the third metal plate 203, and the fourth metal plate 204.

The semiconductor module 200 can further include a wiring member 207 that is located between the first conductive member 201 and the second conductive member 202 in the first direction Z and is electrically connected with the gate electrode 103G of the third chip 103. The gate electrode 103G of the third chip 103 is electrically connected with a wiring layer formed in the wiring member 207 via a connection member 208. For example, a spring pin can be used as the connection member 208. The third chip 103 is switched on and off by a gate voltage applied to the gate electrode 103G via the wiring member 207.

For example, the state in which the first to third chips 101 to 103 are clamped between the first conductive member 201 and the second conductive member 202 is maintained by the fastening force of a screw connected to the first and second conductive members 201 and 202. Pressure along the first direction Z is applied to the first to third chips 101 to 103.

The semiconductor module 200 further includes a second bonding member 52 (shown in FIG. 1) that is located between the second conductive member 202 and the second chip 102 and electrically connects the second conductive member 202 and the second electrode 22 of the second chip 102. A material similar to that of the first bonding member 51 can be used as the material of the second bonding member 52.

The protective film 40 of the second chip 102 includes a second recess 42 in the surface (the upper surface in FIG. 1) of the protective film 40 of the second chip 102 facing the second conductive member 202. A portion of the second bonding member 52 is located in the second recess 42.

As the operation of switching the third chip 103 on and off is repeated, the first bonding member 51 tends to flow due to the repeating thermal expansion and contraction between the first chip 101 and the second chip 102. Similarly, the second bonding member 52 tends to flow due to the repeating thermal expansion and contraction between the second conductive member 202 and the second chip 102.

According to the embodiment above, by including the first recess 41, the first bonding member 51 does not easily flow out onto the side surface of the first chip 101 and the side surface of the second chip 102 even when the first bonding member 51 flows easily. Similarly, by including the second recess 42, the second bonding member 52 does not easily flow out onto the side surface of the second chip 102 and the side surface of the first chip 101. As a result, unintended short-circuit defects can be suppressed, and a semiconductor module with high reliability can be provided.

Similarly to the first recess 41 of the first chip 101, it is favorable for the second recess 42 to be a trench continuously surrounding the second electrode 22 of the second chip 102 when the second surface 10B of the second chip 102 is viewed in plan.

The second surface 10B of the semiconductor part 10 may be flat, as in a modification of the first chip 101 (or the second chip 102) shown in FIG. 6. Also, multiple third semiconductor layers 13 that are arranged to be separated from each other in a plane crossing the first direction Z may be included. The second electrode 22 may have a stacked structure of a first layer 22A, a second layer 22B, and a third layer 22C. The first layer 22A is located on the second surface 10B of the semiconductor part 10 and contacts the third semiconductor layer 13. The first layer 22A includes, for example, Ni. The second layer 22B is located on the first layer 22A and includes, for example, Ti. The third layer 22C is located on the second layer 22B and includes, for example, Au.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a first chip and a second chip stacked in a first direction; and
a first bonding member located between the first chip and the second chip in the first direction,
the first chip and the second chip each including
a semiconductor part including
a first surface, and
a second surface positioned at a side opposite to the first surface in the first direction,
a first electrode located at the first surface,
a second electrode located at a portion of the second surface, and
a protective film partially covering the second surface, the protective film including an opening that exposes the second electrode,
the first bonding member being located between the first electrode of the second chip and the second electrode of the first chip in the first direction and between the first electrode of the second chip and the protective film of the first chip in the first direction,
the first bonding member electrically connecting the second electrode of the first chip and the first electrode of the second chip in the opening of the protective film of the first chip,
the protective film of the first chip including a first recess in a surface of the protective film of the first chip facing the first electrode of the second chip,
a portion of the first bonding member being located in the first recess.

2. The semiconductor device according to claim 1, wherein
the first recess is a trench continuously surrounding the second electrode when the second surface is viewed in plan.

3. The semiconductor device according to claim 1, wherein
the first chip and the second chip each are diode chips, and
the semiconductor part includes:
a first semiconductor layer located on the first electrode, the first semiconductor layer being of a first conductivity type;
a second semiconductor layer located on the first semiconductor layer, the second semiconductor layer being of the first conductivity type and having a lower first-conductivity-type impurity concentration than the first semiconductor layer; and
a third semiconductor layer located on the second semiconductor layer, the third semiconductor layer being electrically connected with the second electrode, the third semiconductor layer being of a second conductivity type.

4. The semiconductor device according to claim 3, further comprising:
a third chip connected in parallel to the first and second chips,
the third chip being a transistor chip including
a third electrode electrically connected with the first electrode of the first chip, and
a fourth electrode electrically connected with the second electrode of the second chip.

5. The semiconductor device according to claim 4, wherein
the third chip is an IGBT (Insulated Gate Bipolar Transistor) chip.

6. The semiconductor device according to claim 3, wherein
the second surface of the semiconductor part includes:
an element region in which the third semiconductor layer is positioned; and
a termination region positioned outward of the element region,
the semiconductor part further includes a fourth semiconductor layer positioned on the second semiconductor layer in the termination region, and
the fourth semiconductor layer is of the second conductivity type and has a lower second-conductivity-type impurity concentration than the third semiconductor layer.

7. The semiconductor device according to claim 1, wherein
the semiconductor part is made of silicon carbide.

8. A semiconductor module, comprising:
a plurality of the semiconductor devices according to claim 4;
a first conductive member; and
a second conductive member,
the plurality of semiconductor devices being located between the first conductive member and the second conductive member in the first direction,
the first electrode of the first chip and the third electrode of the third chip being electrically connected with the first conductive member,
the second electrode of the second chip and the fourth electrode of the third chip being electrically connected with the second conductive member.

9. The semiconductor module according to claim 8, further comprising:
a second bonding member located between the second conductive member and the second chip, the second bonding member electrically connecting the second conductive member and the second electrode of the second chip.

10. The semiconductor module according to claim 9, wherein
the protective film of the second chip includes a second recess in a surface of the protective film of the second chip facing the second conductive member, and
a portion of the second bonding member is located in the second recess.

11. The semiconductor module according to claim 10, wherein
the second recess is a trench continuously surrounding the second electrode of the second chip when the second surface of the second chip is viewed in plan.

12. The semiconductor module according to claim 8, further comprising:
a wiring member located between the first conductive member and the second conductive member in the first direction,
the wiring member being electrically connected with a gate electrode of the third chip.
